(19) United States
(12) Patent Application Publication
(10) Pub. No.: US 2012/0025210 A1
(43) Pub. Date: Feb. 2, 2012

(54) OPTICAL MODULE ENCLOSING LEAD FRAME AND SEMICONDUCTOR OPTICAL DEVICE MOUNTED ON THE LEAD FRAME WITH TRANSPARAENT MOLD RESIN

(75) Inventors: Tomoya Saeki, Yokohama-shi (JP); Toshio Mizue, Yokohama-shi (JP)

(73) Assignee: SUMITOMO ELECTRIC INDUSTRIES, LTD., Osaka-shi (JP)

(21) Appl. No.: 13/148,236

(22) PCT Filed: Feb. 18, 2010
(86) PCT No.: PCT/JP2010/052908

§ 371 Date: Aug. 5, 2011

(30) Foreign Application Priority Data
Feb. 19, 2009 (JP) 2009-036328
Feb. 20, 2009 (JP) 2009-037419
Feb. 20, 2009 (JP) 2009/037420

(51) Int. Cl. H01L 33/62; H01L 21/50

(52) U.S. Cl. 257/81; 257/676; 438/123; 257/E33.066; 257/E21.499

(57) ABSTRACT

An optical module with a new arrangement is disclosed. The optical module molds devices with a resin transparent to light subject to the device mounted on the lead frame and electrically connected with the lead frame by the bonding wire. The lead frame provides a screen apart from the device by a distance substantially comparable with a dimension of the device. The screen compensates the stress induced in the bonding wire due to a large discrepancy on the thermal expansion coefficient of the transparent resin.

### TECHNICAL FIELD

The present invention relates to an optical module applicable to the optical communication system, in particular, the invention relates to an optical module that encloses a read frame and a semiconductor optical device mounted on the read frame with resin transparent for light subject to the semiconductor optical device.

### BACKGROUND ART

An optical module with transparent resin to mold a semiconductor optical device has been well known in the fields. For example, Japanese Patent Applications published as JP-2007-142278A and JP-2001-074985A have disclosed an optical module that encloses a semiconductor optical device with resin transparent for light subject to the semiconductor optical device and provides a lens to concentrate light fowled by an outer shape of the molding resin. Because the transparent resin contains no filler to adjust the thermal expansion thereof, the resin has a large thermal expansion coefficient, although it becomes transparent. Consequently, the resin causes a large thermal stress against components enclosed therein. Especially, bonding wires that electrically connect the lead frame with the semiconductor device are the weakest for the stress among components within the resin; accordingly, the thermal stress caused by a large thermal expansion coefficient of the transparent resin breaks the bonding wire, or degrades the reliability of the wire at a portion where the cross section thereof narrows.

The present invention provides an improved arrangement that may reduce the thermal stress caused by the transparent resin with no filler to compensate the thermal expansion co-efficient where the semiconductor devices and electrical components are molded with such a resin.

### SUMMARY OF INVENTION

One aspect of the present invention relates to an optical module in which a semiconductor optical device and a lead frame mounting the semiconductor optical device, where they are electrically connected with a bonding wire, are molded with resin transparent to light subject to the semiconductor optical device. Because the resin is free from filler to compensate the performance thereof, the thermal expansion co-efficient becomes considerably greater than those ordinarily used. Therefore, a stress is induced against the components molded therein by the change of the ambient temperature and/or the thermal process such as soldering the lead frame. The stress concentrates on a portion with physically intolerant components in particular, when the stress concentrates on the bonding wire, it sometimes results in the breakage.

The optical module according to the present invention provides a screen to compensate the stress induced in the bonding wire. The screen of the invention is a portion of the lead frame and is apart from a distance comparable to a physical dimension of the semiconductor optical device. The screen may be formed so as not only to extend along one edge of the device but to surround the semiconductor optical device, and/or to cover a space immediately above the semiconductor optical device.

The optical module of the present invention may provide the resin with a pillar portion that encloses the semiconductor optical device and so on, and a planar portion that extracts the lead frame. The optical module may further provide a tubular member that covers the pillar portion in adhered thereto. The tubular member may physically restrict the expansion of the pillar portion; the stress induced in the bonding wire may be compensated.

Furthermore, the planar portion of the transparent resin may provide a window that exposes the lead frame molded within the resin. Soldering the read frame as a member comes in contact with the lead frame exposed in the window; the heat due to the soldering may be effectively restricted to conduct inside of the resin. Moreover, the characteristic impedance of the lead frame may be substantially unvaried by filling a material with the dielectric constant thereof substantially equal to the transparent resin after the soldering is carried out.

### BRIEF DESCRIPTION OF DRAWINGS

The foregoing and other purposes, aspects and advantages will be better understood from the following detailed description of a preferred embodiment of the invention with reference to the drawings, in which:

FIG. 1A is a perspective view of an optical module according to the first embodiment of the present invention, in which dotted lines denote the shape of the transparent resin; and FIG. 1B magnifies a primary portion that mounts a semiconductor optical device on the lead frame;

FIG. 2 illustrates the lead frame, which mounts the semiconductor optical device thereon shown in FIG. 1A, viewed from a side opposite to the primary portion shown in FIG. 1B;

FIG. 3 shows a first modified example of the optical module shown in FIG. 1A;

FIG. 4 shows parameters to evaluate an effect of the new arrangement appeared in the first embodiment shown in FIG. 1A;

FIG. 5 shows parameters to evaluate an effect of the first modified embodiment shown in FIG. 3;

FIG. 6 shows a second modified example of the optical module shown in FIG. 1A and parameters to evaluate an effect of the modified arrangement thereof;

FIGS. 7A to 7C show results of the effect in the first embodiment shown in FIG. 1, where FIGS. 7A to 7C show relations of the stress caused in the bonding wire against a distance from the wire, the height, and the width of the screen;

FIGS. 8A and 8B show results of the effect appeared in the first modified embodiment shown in FIG. 3, where the stress appeared in the wire are shown against the length of the sub-screen, and the gap between the sub-screens;

FIG. 9 shows an effect by the second modified embodiment shown in FIG. 6, where the stress caused in the wire is shown against the width of the ceiling of the screen;

FIGS. 10A to 10D show an optical module according to the second embodiment of the present invention, where FIG. 10A is an exploded drawing of the optical module and the sleeve member, FIG. 1013 is a perspective view of the optical subassembly that assembles the optical module with the sleeve member, FIG. 10C is a cross section taken along the optical axis of the optical sub-assembly, and FIG. 10D is a plan view showing the lead frame in the optical module and devices mounted on the lead frame;

FIGS. 11A to 11D shows the arrangement of the optical module shown in FIGS. 10A to 10D, where FIG. 11A is a perspective view, FIG. 11B is a plan view, FIG. 11C is a cross section of the pillar portion of the transparent resin, and FIG. 11D shows a tube covering the pillar portion of the transparent resin;

FIGS. 12A and 12B show effects of the tube, where FIG. 12A shows a stress caused in the bonding wire against the thickness of the tube, while, FIG. 12B shows a stress against the width of the tube along the longitudinal direction of the module;

FIG. 13 shows a modified arrangement of a lead frame shown in FIGS. 10A to 10D, where the modified lead frame has a portion bent upward to show a function of a mirror that reflects light coming from the laser diode toward the monitor PD;

FIGS. 14A to 14C show processes to manufacture the optical module of the second embodiment shown in FIGS. 10A to 10D;

FIG. 15 is a perspective view of a transparent resin modified from the resin shown in FIG. 1 or FIGS. 10A to 10D;

FIG. 16 is a plan view of the modified resin shown in FIG. 15; and

FIG. 17 shows an assembly including the optical sub assembly shown in FIG. 15 electrically connected with a flexible printed circuit board.

### DESCRIPTION OF EMBODIMENTS

### First Embodiment

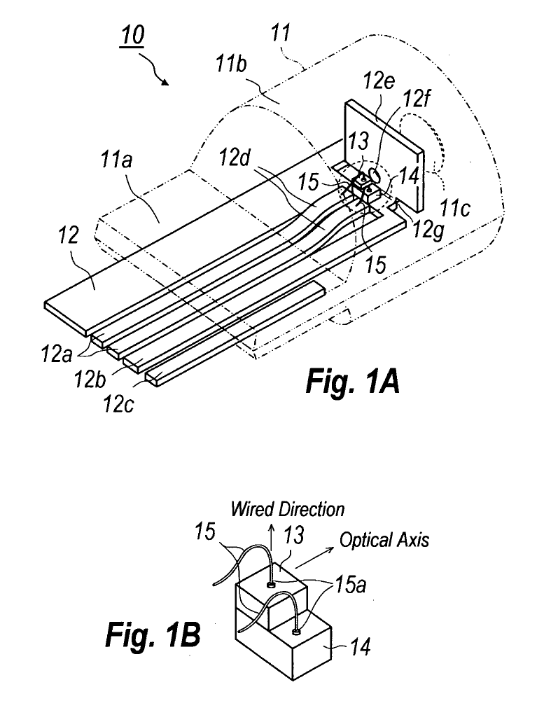

FIG. 1A is a perspective view of an optical module according to the first embodiment of the present invention; while, FIG. 1B magnifies a primary portion of the optical module 10 where the LD 13 is mounted on the lead frame 12. The optical module 10 of the present embodiment comprises the mold resin 11 transparent to the light subject to the semiconductor optical device molded therein, the lead frame 12, the semiconductor optical device 13, and the sub-mount 14. The semiconductor device 13 is mounted on the lead frame 12 through the sub-mount 14. The semiconductor device 13 may be a laser diode (hereafter denoted as LD), or a photodiode (hereafter denoted as PD). The description presented below primarily concentrates on an optical module that encloses the LD therein, however, the subjects of the present invention may be applicable in a similar manner to an optical module that encloses the PD, or to an optical module that encloses the LD and the PD.

The optical module 10 shown in FIG. 1A encloses the LD 13 mounted on the sub-mount 14 with the transparent resin 11. The mold resin 11 includes a planar portion 11a and a pillar portion 11b. The LD 13 is molded in the pillar portion 11b, while, the planar portion 11a extrudes the lead frame 12 in the end opposite to the pillar portion 11b. A center of the pillar portion 11b provides a lens 11c formed by the outer shape of the mold resin 11 to concentrate the light emitted from the LD 13. The mold resin 11 of the present embodiment, each of the planar portion 11a and the pillar portion 11b, has a function transparent to the light subject to the LD 13.

The lead frame 12 is extracted from the end of the planar portion 11a. The lead frame 12 includes signal leads 12a electrically connected with the LD 13 via the bonding wire 15, the ground lead 12b that mounts the LD 13 through the sub-mount 14, and another lead 12c through which a signal generated by a monitor PD, which is not shown in FIG. 1A, that monitors the magnitude of the light emitted from the LD 13. The signal leads 12a is put between the ground leads 12b to reduce the external noise affected to the signal leads 12a. The signal leads 12a are bent 12d in a side close to the LD 13 to shorten the length of the bonding wire 15 drawn from the lead 12a to the LD 13.

The optical module 10 according to the present embodiment provides a screen 12e, which is a portion of the lead frame 12 bent upward by about 90° at a portion close to the LD 13 so as to be along the edge of the LD 13. As explained later, the screen 12e very close to the LD 13 may reduce the stress induced in the bonding wire 15 connected to the LD 13. That is, the screen 12e may compensate the stress caused between the mold resin 11 and the lead frame 12 to prevent the bonding wire 15 from breaking.

The transparent resin 11 includes no additive, which is often called as filler, to make the resin transparent for the light subject to the LD 13. Because the filler may reduce the thermal expansion co-efficient of the resin, the transparent resin 11 of the present embodiment has an expansion co-efficient about four (4) times greater than that of the components molded therein, such as metal lead frame 12, and causes a large thermal stress against such components due to the ambient temperature of the optical module 10 and the heat generated by the LD 13. When such thermal stress is applied to the bonding wire 15, which is one of the weakest components within the resin 11, the wire 15 probably and easily breaks.

FIG. 1B schematically illustrates a shape of the bonding wire 15 that is bonded to the pad on the LD 13 and that on the sub-mount 14. An ordinary wire bonding extends the bonding wire 15 in a direction perpendicular to the bonding pad. Moreover, when the bond strength between the bonding wire 15 and the bonding pad satisfies an ordinary condition, the stress caused by the discrepancy of the thermal expansion co-efficient concentrates on a neck portion of the bonding wire 15, that is, a portion immediately close to the bonding pad and a portion where the diameter of the wire drastically varies. The screen 12e may reduce the stress concentrated on the neck portion of the bonding wire 15.

The screen 12e provides an opening 12f in a center thereof to pass the light emitted from the LD 13 therethrough. Although the embodiment shown in FIG. 1 forms an opening 12f with a circular shape, it is unrestricted for the opening 12f to be circular. A V-shaped cut or a U-shaped cut formed from the edge of the screen 12e toward the center thereof may be applicable. The light emitted from the LD 13 passes the opening 12f and is concentrated or collimated by the lens 11c formed in the surface of the transparent resin 11 to be provided outside of the module 10. The lead frame 12 of the present embodiment may be made of cupper alloy or Fe—Ni alloy with a thickness of 0.1 to 0.2 mm.

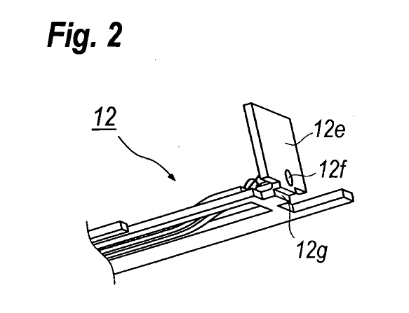

Referring to FIG. 2, the lead frame 12 further provides a thinned portion 12g in the back side of the screen 12e, which facilitates the bend of the screen 12e. Forming a thinned portion 12g in the back surface of the lead frame 12 with a chisel first, the lead frame 12 is to be bent upward along the thinned portion 12g after the wire bonding between the LD 13 and the lead frame 12 is carried out. As explained later, the present embodiment is preferable for the screen 12e as close as possible to reduce the stress induced in the bonding wire 15, for instance, the screen 12e is preferably close to the LD 13 within a distance substantially equal to a size of the LD 13. Accordingly, it is exceedingly effective to make the thinned portion 12g in the back surface of the lead frame 12 in advance to bend it.

Next, a process to manufacture the optical module 10 of the present embodiment will be described. The optical module 10 may be completed through processes below: first, the LD 13 and other components are mounted on the lead frame 12 through the sub-mount 14 or directly thereon, where the lead frame 12 has a plurality of inner leads, 12a to 12c, supported by an support lead surrounding the inner leads, 12a to 12c. Because the inner leads, 12a to 12c, are supported by the support lead with tie bars, the inner leads, 12a to 12c, could not be disassembled. Next, the wire bonding connects respective bonding pads of the LD 14, the PD and the sub-mount 14 with the lead frame 12. Thermo-compression bonding or the ultrasonic bonding, or using them concurrently may be applicable. Then, thus assembled lead frame 12 with the components thereof is bent upward in the screen 12e along the thinned portion 12g, and is set within a cavity of the molding die. The molding die generally comprises an upper die, a lower die and a lens die, where they form the cavity into which the lead frame 12 is set. The shape of the cavity corresponds to the outer shape of the transparent resin 11.

Then, a molding resin is injected within the cavity. One of the upper and lower dies provides a port to inject the resin, while, the other or the same die provides another port to deflate the air or the inert atmosphere. When the screen 12e provided in immediate to the LD 13 is substantially perpendicular to the injection port, the injected resin occasionally is insufficiently filled within the cavity by the existence of the screen 12e. Accordingly, the screen 12e is preferably to be set so as to be in substantially parallel to the injection port. Further, in order to reduce the stress to the bonding wire 15 caused by the flow of the injected resin, the injection port preferably locates in a direction extending the bonding wire 15, that is, in a direction substantially perpendicular to the primary surface of the lead frame 12. Injecting resin and solidifying them, the lens die is firstly removed then the upper and lower dies are detached to complete the resin molding. Finally, cutting the tie bars supporting the inner leads, 12a to 12c, the optical module 10 with the transparent resin to enclose the optical and electrical components therein is completed.

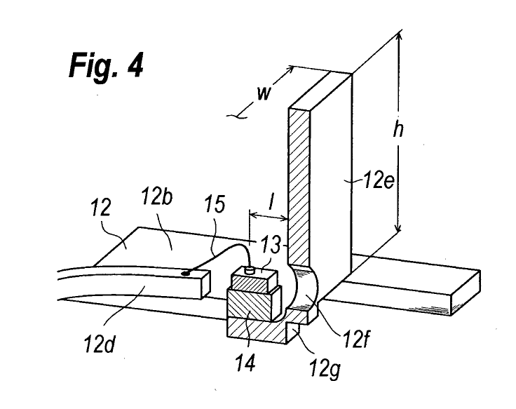

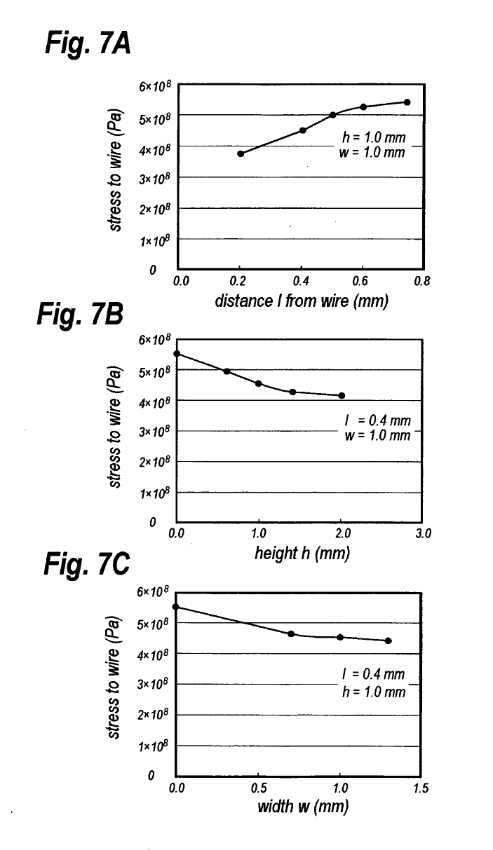

FIGS. 7A to 7C evaluate the function of the screen 12e according to the embodiment of the invention. Physical parameters used in the evaluation are shown in FIG. 4 and listed in the table blow; in which the width of the screen 12e is denoted as w, the height from the primary surface of the lead frame 12 is shows as h, and the distance from the bonding wire 15 at the pad of the LD 13 is shown as l. The evaluation is done through the stress caused in the bonding wire 15.

TABLE
Physical parameters used in evaluation

| | | | linear expansion |
|---|---|---|---|
| element | material | Young's Modulus | co-efficient |
| LD | InP | 82.7 | 4.50 × 10⁻⁶ |
| Sub-mount | AlN | 320.0 | 4.70 × 10⁻⁶ |
| PD | InP | 82.7 | 4.50 × 10⁻⁶ |
| Lead frame | Cu-alloy | 125.0 | 1.75 × 10⁻⁵ |
| Au wire | Au | 78.0 | 1.42 × 10⁻⁵ |
| mold resin | epoxy | 3.2 | 6.50 × 10⁻⁵ |
| adhesive | epoxy | 7.0 | 3.00 × 10⁻⁵ |

Referring to FIGS. 7A to 7C, conditions where the distance 1 from the bonding wire 15 is large enough, the width of the screen 12e becomes 0, and the height h thereof becomes 0 are corresponding to the case where no screen 12e is formed. The function of the screen 12e may be evaluated through how the stress caused in the bonding wire 15 may be reduced compared with the case where no screen 12e is provided.

Referring to FIG. 7A, a stress of about 550 MPa is induced in the bonding wire 15 for the case of no screen 12e. Setting the screen 12e in a distance of about 0 5 mm, which is about twice of the dimensions of the LD 13, the stress may be reduced to 500 MPa, and setting the screen 12e closer to the LD 13, about 0.4 mm from the LD 13, the stress may be reduced to 450 MPa, which means the 18% reduction from the initial condition. The bonding wire 15 is not always broken even in the case without the screen 12e. Exposing the module 10 under a condition of 85° C. and 85% of the humidity, the breakage of the bonding wire 15 is found in only a few modules. Therefore, the reduction of the stress from 550 MPa to 500 MPa may result in an extremely increase of the reliability of the module. Closing the screen 12e to about 0.2 mm, which is comparable to the size of the LD 13, the stress may decrease to 400 MPa or less.

FIG. 7B shows the evaluation of the stress against the height of the screen 12e. In this evaluation, the distance from the bonding wire 15 is set to be 0.4 mm and the width of the screen 12e is assumed to be 1 mm. Referring to FIG. 7B, the stress monotonically decreases as the height h increases. But, the effect thereof reduces when the height exceeds 1 mm and saturates over 1.5 mm. To increase the height h of the screen 12e means that the diameter of the pillar portion 11b of the molding resin 11 increases. Based on the continuous requests to make the size of the module smaller, the diameter of the pillar portion 11b is probably 5 mm in a maximum. Accordingly, the height h of the screen 12e is restricted to be 5 mm, a half of the possibly maximum diameter. The evaluation shown in FIG. 7B enough satisfies the restriction, that is, the stress induced in the bonding wire 15 may be reduced without expanding the diameter of the pillar portion 11b of the molding resin 11.

FIG. 7C evaluates the effect of the width w of the screen 12e to the stress appeared in the bonding wire 15, where the height h and the distance 1 to the bonding wire 15 are assumed to be 1 mm and 0.4 mm, respectively. Setting the width w of the screen 12e at least 0.75 mm, the stress may be decreased by at least 18% compared with the case of no screen 12e. But, even further increasing the width w of the screen 12e, the reduction of the stress is restricted. An enough wide screen 12e may reduce the stress only by about 20%. Thus, based on the evaluation shown in FIGS. 7A to 7C, the screen 12e as closer to the LD 13 or the bonding wire 15 as possible is most effective to reduce the stress induced in the bonding wire 15. However, a condition of the zero (0) distance is physically impossible, while, taking the process to bend the screen 12e after the wire bonding into account, the screen 12e may be practically set apart from the LD 13 by about 0.4 mm, which is comparable to the size of the LD 13.

(First Modification)

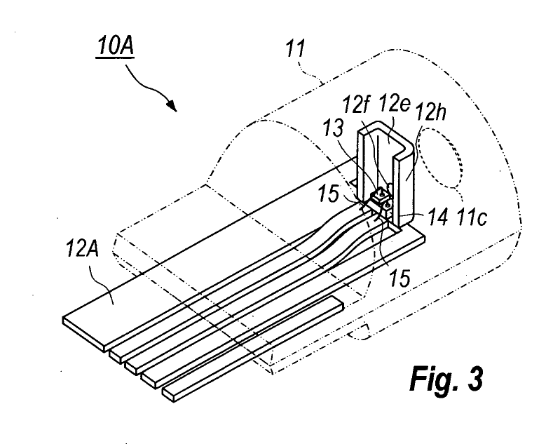

FIG. 3 shows a modification of the first embodiment. The optical module 10A shown in FIG. 3 provides another lead frame 12A different from the lead frame 12 of the first embodiment shown in FIG. 1A. That is, the present lead frame 12A provides sub-screens 12h in addition to the screen 12e so as to put the LD 13 therebetween, but the screen 12e of the present embodiment also provides, as that in the first embodiment, the opening 12f to pass the light emitted from the LD 13.

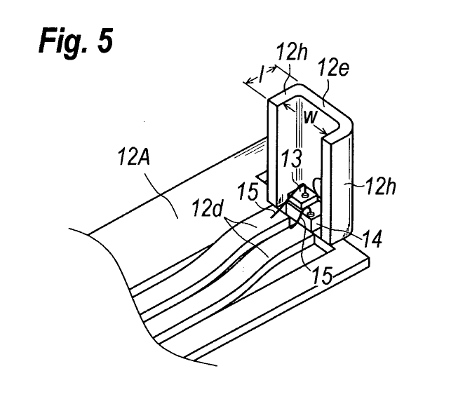

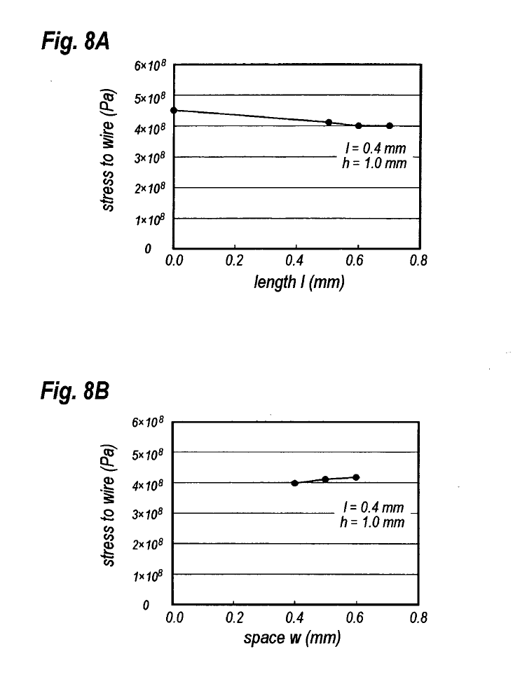

FIGS. 8A and 8B evaluate the function of the screen 12e and the sub-screens 12h shown in FIG. 3, where parameters appeared in FIGS. 8A and 8B correspond to those denoted in FIG. 5. The width w of the screen 12e is a gap between the sub-screens 12h, while, the length l of the sub-screen 12h corresponds to the outer length thereof. Referring to FIGS. 8A and 8B, the sub-screen 12h shows substantial effect to the reduction of the stress induced in the bonding wire 15, but, the effectiveness thereof is slighter than that of the screen 12e. Increasing the length l of the sub-screen 12h from 0 to 0.6 mm, where the length l equal to 0 corresponds to a case without any sub-screen 12h, the stress may be compensated by about 10%, but, it indicates to saturate over 0.5 mm. Similarly, even when the gap w between the sub-screens 12h decreases, the stress becomes not less than 400 MPa. In those evaluations, the distance from the screen 12e to the bonding wire 15 and the height of the screen 12e and that of the sub-screens 12h are assumed to be 0.4 mm and 1 mm, respectively:

(Second Modification)

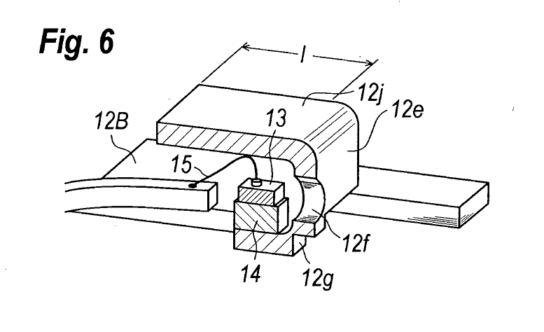

FIG. 6 shows still another modification of the optical module 10. The optical module of the present embodiment provides another lead frame 12B that has an overhang 12j to cover the upper space of the LD 13. The overhang 12j is bent at the end of the screen 12e rearward by about 90° to cover the upper space of the LD 13.

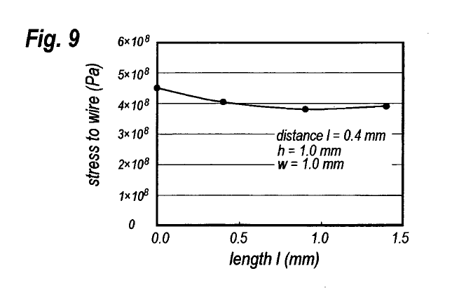

FIG. 9 evaluates the effect of the overhang 12j in a length l thereof against the stress induced in the bonding wire 15. The length l equal to 0 mm corresponds to a case of the screen 12e without any overhang, at which the stress becomes about 450 MPa substantially equal to cases shown in FIGS. 7A to 7C. Expanding the length l of the overhang 12j, the stress may be equal to 400 MPa or lower at the length l equal to 1 mm, which means that the existence of the overhang 12j may be effective independent of the length thereof to compensate the stress induced in the wire 15. The evaluation above assumes that the distance from the bonding wire 15, the height and the width of the screen 12e are 0.4 mm, 1 mm and 1 mm, respectively.

### Second Embodiment

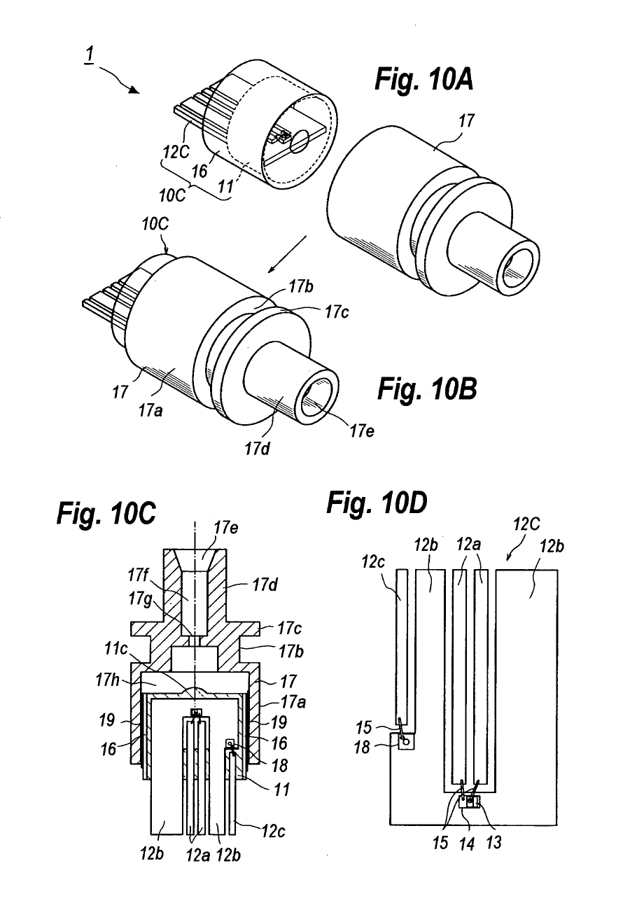

FIGS. 10A to 10D show an optical module according to the second embodiment of the present invention. The optical module 10C shown comprises a lead frame 12C, a molding resin 11 and a tubular member 16, and the optical module 10C constitutes an optical subassembly 1 assembled with the coupling member 17. The tubular member 16 may be made of metal including copper alloy and nickel-iron alloy that covers the pillar portion 11b of the molding resin 11. As described later, the tubular member 16 may be assembled with the transparent resin 11 at the molding process, no air or no gap is put between the tubular member 16 and the transparent resin 11. The optical subassembly 1 may be formed by inserting thus assembled optical module 10C with the tubular member 16 into a bore of the coupling member 17 and gluing them. The function of the tubular member 16 to reduce the stress to the bonding wire 15 will be described later.

FIG. 10D is a plan view of the lead frame 12C installed in the optical module 10C of the present embodiment. The lead frame 12C provides the ground leads 12b having the U-plane shape putting the signal lead 12a with in the U-shape. The ground lead 12b mounts the LD through the sub-mount 14 in a position corresponding to the bottom of the U-shape. One of the ground lead 12b directly mounts the monitor PD 18 without a sub-mount 14. The signal generated by the monitor PD 18 is lead through the other lead 12c. The electrical connections of the LD 13, the sub-mount 14 and the monitor PD 18 with the corresponding lead are performed by the bonding wires 15.

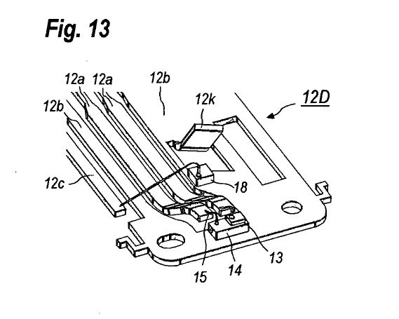

FIG. 13 shows another arrangement to mount the monitor PD 18 on the lead frame 12D. In the arrangement shown in FIG. 13, the ground lead 12b with the U-shape, a pair of signal leads, and the signal lead 12c for the monitor PD 18 are substantially same with those of the lead frame 12C. The lead frame LW in FIG. 13 has a feature that the monitor PD 18 is mounted on the other ground lead 12b, not the ground lead 12b adjacent to the signal lead 12c, and this ground lead 12b mounting the PD 18 provides a tab 12k picked upward behind the PD 18. The light emitted from the back facet of the LD 13 enters the monitor PD 18 by being reflected at the surface of this tab 12k. Because the light emitted from the LD 13 is dispersive, the arrangement of the monitor PD 18 shown in FIG. 1 or FIG. 10, where no optical members reflecting the light from the LD 18 is placed, may receive the dispersive light from the LD 18. However, the optical member 12k to reflect the light provided behind the LD 13 may strengthen the magnitude of the light which the monitor PD 18 is detectable.

Referring back to FIGS. 10B and 10C, the optical module 10C with the tubular member 16 is inserted into the bore 17h of the coupling member 17. The coupling member 17 with a co-axial shape provides a first tube 17d that forms a first bore 17f extending from an end so as to receive a ferrule attached in a tip of the external fiber, while, another tube 17a in the other end that forms the bore 17h to receive the optical module 40C. These two bores, 17f and 17h, are connected with the third bore 17g whose diameter is smaller than those of two bores, 17f and 17h. Furthermore, between two tubes, 17a and 17d, is fowled with a neck 17b and a flange 17c, which may optically align the optical subassembly 1. The end 17e of the first bore 17f is chamfered to facilitate the insertion of the ferrule.

The optical module 10C may be assembled with the coupling member 17 by applying an adhesive on the outer surface of the tubular member 16 and inserting it into the bore 17h. The optical module 10C may be optically aligned by adjusting a depth of the insertion into the bore 17, which performs the alignment along the optical axis, and by slightly shifting the module 10C within the bore 17h, which performs the alignment in a plane perpendicular to the optical axis. Because a slight gap is formed between the tubular member 16 and the inner surface of the bore 17h, the optical module 10C may be slightly moved within the bore 17h. Solidifying the adhesive after the optical alignment described above, the optical module 10C may be assembled with the coupling member 17.

(Third Modification)

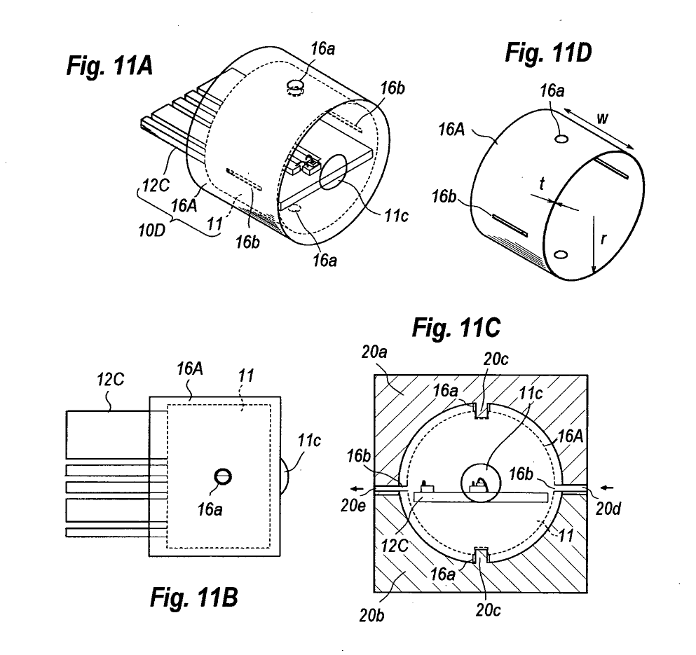

FIGS. 11A to 11D illustrate a modified tubular member 16A. This tubular member 16A also covers the pillar portion 11b of the transparent resin 11. The tubular member 16A has a feature compared with the tubular member 16 shown in FIGS. 10A to 10D that the tubular member 16A of the present embodiment provides two openings 16a and two slits 16b, where they are alternately formed with a rotation of about 90°.

Two openings 16a are prepared to receive the positional pins when the tubular member 16A is set within the molding cavity. That is, referring to FIG. 11C, after mounting components on the lead frame 12C and electrically connecting the components with the lead frame 12C, the intermediate assembly is set within the molding cavity. In an example, the upper die 20a and the lower die 20b each provides a pin 20c. The pin in the lower die 20b is inserted into one of the opening 16a of the tubular member 16A, while, the other opening 16a receives the pin 20c prepared in the upper die 20a when the upper and lower dies, 20a and 20b, are joined. Thus, the tubular member 16A may be aligned with the dies, then, the injection port 20d provided in the upper die 20a may be aligned with one of the slit 16b of the tubular member 16A, while the other slit 16b may be aligned with the deflation port 20e automatically, which may facilitate the injection of the molding resin into the cavity and the tubular member 16A fully covers the pillar portion 11b of the molding resin to compensate the stress induced in the bonding wire 15.

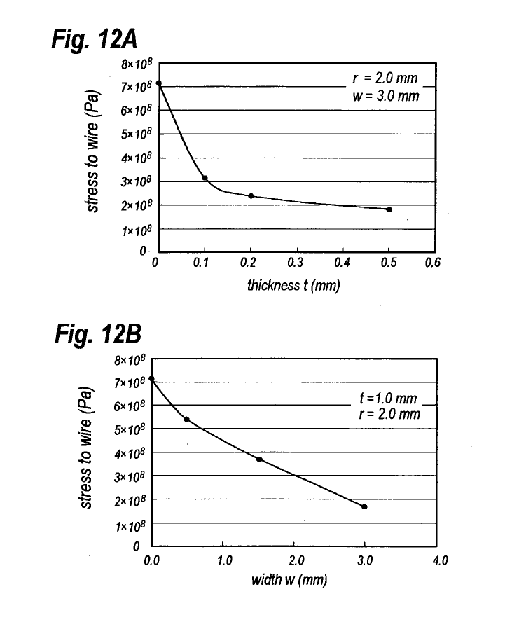

The function of the tubular member 16A with dimensions shown in FIG. 11D is evaluated. FIG. 12A evaluates the thickness t of the tubular member 16A against the stress, where a condition t=0 mm corresponds to a case without the tubular member. Referring to FIG. 12A, even the thickness t of the tubular member 16A is only 0.1 mm, enough compensation may be anticipated for the bonding wire 15, but, the effectiveness of the compensation is restricted or saturates even when the thickness t is greater than 2 mm. The thickness t of 2 mm is comparable with that of the lead frame 12; accordingly, the tubular member 16A is quite effective even when the member 16A is made of material same with that of the lead frame 12A.

FIG. 12B evaluates the stress to the bonding wire 15 against the width w of the tubular member 16A. The stress may be compensated by about 70% by the existence of the tubular member 16A with the width thereof only 3 mm. The tubular member 16 whose width w is only 1 mm may reduce the stress about 35%. As already described, the bonding wire 15 is not always broken even in a case of no tubular member, which corresponds to the width of 0 mm. Reliability of a level, in which the possibility for the wire to be broken substantially increases by iterating the harsh environment conditions, is subject to the present invention. The compensation of a few tens of percentages be accomplished by the tubular member 16A would bring an extreme increase in the reliability of the optical module 10C. In the evaluations shown in FIGS. 12A and 12B, physical constants of the components are used listed in the table above, and the tubular member 16A has a material made of cupper alloy.

Additionally, the compensation of the stress by the tubular member 16A is far greater than that due to the screen 12e formed in the lead frame 12 according to the first embodiment shown in FIG. 1. Because the tubular member 16A covers and tightens the whole outer surface of the transparent resin 11, which effectively restricts the swell of the resin 11, in particular, the swelling toward a direction of the extension of the bonding wire 15.

(Fourth Modification)

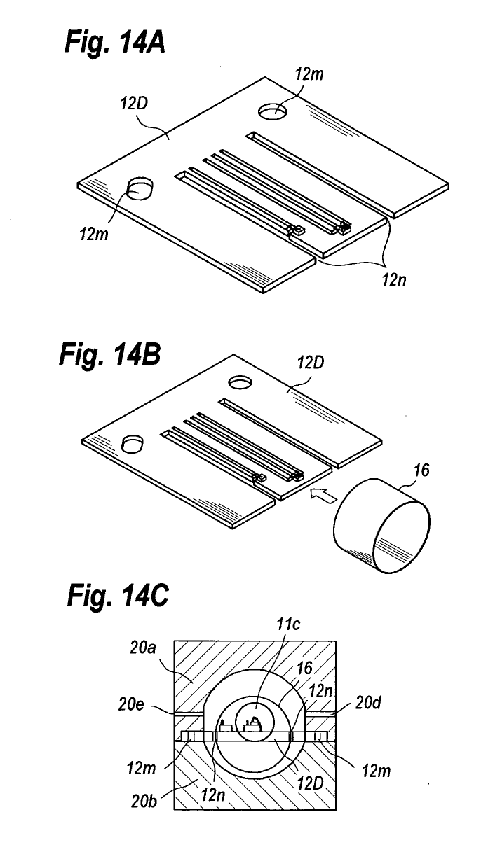

FIGS. 14A to 14C describe the fourth modified example according to the present invention. The optical module 10A according to the second embodiment shown form FIG. 10 to FIG. 12 provides the tubular member, 16 or 16A, so as to cover the outer surface of the transparent resin 11. The optical module 10B of the present embodiment implements the tubular member 16 within the transparent resin 11. FIGS. 14A to 14C, each describes the process to manufacture the optical module 10B that provides the lead frame 12D. The lead frame 12D provides a pair of slits 12n in the outsides of the ground leads 12b. An interval between the slits 12n is substantially equal to the diameter of the tubular member 16. The process is carried out as follows: first inserting the tubular member 16 into the slits 12n as shown in FIG. 14B, then setting the intermediate assembly of the tubular member 16 with the lead frame 12D on which the components are mounted and wire-bonded on the lower die 20b. Because the space between the slits 12n is substantially equal to the diameter of the tubular member 16, the tubular member 16 may be assembled with the lead frame 12D only by inserting it into the slits 12n.

The lower die 20b extrudes the pin that passes through the opening 12m formed in the lead frame 12D. This pin in the lower die 20b has a function to align the upper die 20a with the lower die 20b, accordingly, setting the upper die 20a as receiving the pin in the hole provided therein, the cavity 20f for the molding is formed into which the lead frame 12D with the tubular member 16 is set. Then, injecting the resin from the injection port 20d as exhausting the air left in the cavity 20f from the deflation port 20e, the transparent resin is molded. As illustrated in FIG. 14C, the center of the tubular member 16 is offset from the center of the pillar portion 11b of the resin because the center of the pillar portion 11b is necessary to be aligned with the optical axis of the LD 13 which is mounted on the lead frame 12D through the sub-mount 14. Moreover, the pillar portion 11b of the molding resin practically has an outer shape of an expanded circular with linear edges. This is because the upper and lower dies, 20a and 20b, are easily removed from the module 10A after the molding.

The tubular member 16 molded within the resin 11 according to this modified embodiment may also effectively compensate the stress induced in the bonding wire 15.

### Third Embodiment

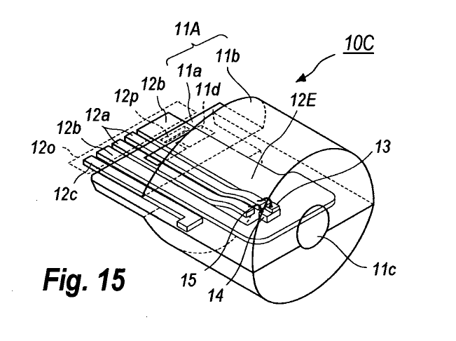

FIG. 15 is a perspective view of an optical module 10C according to the third embodiment of the present invention. The optical module 10C provides the transparent resin 11A which also has the planar portion 11a and the pillar portion 11b. But, the transparent rein DA of the present embodiment has features different from those of the foregoing resin 11 that the planar portion 11a of the present resin 11A provides a window 11d that exposes the ground lead 12b of the lead frame 12E in the bottom thereof, and the ground lead 12b provides another window 12k.

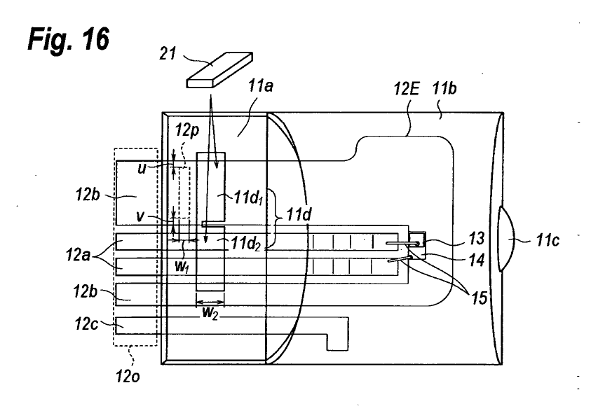

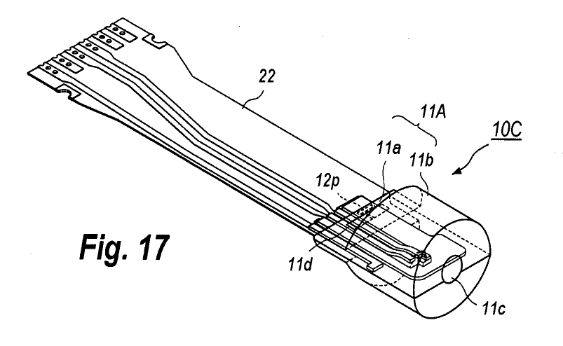

The optical module 10C may be manufactured by processes similar to those for the first and second embodiments, that is, the LD 13 and so on are molded with the resin 11 after they are mounted on and wire-bonded with the lead frame 12E. Then, thus molded module 10C is electrically connected with a host system by soldering, for instance, a flexible printed circuit refer to FIG. 17, to a portion 12o of the lead frame 12E. The lead frame 12E as described in the foregoing shows the thermal conductivity greater than 350 [Wm/K]. Moreover, a temperature for the soldering reaches about 180 to 230° C. depending on types of the solder. Then, heat at the soldering is easily conducted to the other end of the lead frame 12E where the wire 15 is bonded thereto, and causes a large thermal stress in the bonding wire 15 and the lead frame 12E. The optical module 10C according to the present embodiment provides in the planar portion of the molding resin 11A the window 11d to expose the ground lead 12, and in addition to the window 11d, another window 12p in the ground lead 12b so as to traverse the lead 12b. The window 12p in the ground lead 12b narrows the cross section of the ground lead 12h, which increases the thermal resistance of the lead 12b. Not only the window 12p but a notch or a groove may show the function substantially same with the window 12p. Coming a member 21 in contact with the ground lead 12b when the flexible printed circuit board is soldered to the position 12o of the lead frame 12E, the member 21 may effectively dissipate heat conducted from the position 12o to the inside of the molding resin 11A along the lead frame 12E. The member 21 may be a metal block made of copper alloy. The embodiment shown in FIGS. 15 and 16 implements the window 11d in the planar portion 11a and another window 12p in the lead frame 12E; however, only one of the windows, 11d or 12p, may show the function to restrict the heat to be conducted into the mold resin 11A.

FIG. 16 is a plan view of the module 10C implementing two windows, 11d and 12p. The first window 12p formed in the ground lead 12b has a longitudinal width w1 of 0.15 mm; and a rest portion of the ground lead 12b has another width (u+v) of about 0.2 mm. To restrict the heat conduction into the inside of the mold resin 11A, the rest portion of the ground lead is preferably as narrow as possible. However, the width of the ground lead 12b should be wide enough to stabilize the ground potential at high frequency regions in a case that the present module 10C operates in giga-hertz regions. Also, taking the handling of the lead frame 12E during the manufacturing processes of the module 10C, the lead frame 12E is necessary in a thickness thereof at least about 0.2 mm.

The module 10C shown in FIG. 16 provides two windows, 11d₁ and 11d₂, where the former exposes the ground lead 12b while the latter exposes the signal lead 12a. These two windows, 11d₁ and 11d₂, each have a lateral width of 0.5 mm. When the window 11d has a wider lateral width, the heat dissipation through the window 11d becomes further effective, but the planar portion 11a is necessary to be expanded for such a wider window, which results in an enlarged size of the module.

When the operating speed of the optical module 10C reaches or exceeds 10 GHz, the characteristic impedance of the signal lead 12a strongly influences the signal quality transmitting on the signal lead 12a. The characteristic impedance of the signal lead 12a depends on not only the width and the thickness thereof but substances surrounding the signal lead 12a. Providing the window 11d in the resin 11A, the characteristic impedance of the signal lead 12a at a portion fully covered with the resin 11A and that in the window with no substances are considerably mismatched, which degrades the signal quality transmitting on the signal lead 12a. Therefore, the present optical module 10C fills the window 11d with a material whose dielectric constant substantially equal to the transparent resin 11A after the soldering of the circuit board to the lead frame 12E as the member 21 comes in contact with the signal lead 12a and the ground lead 12b to facilitate the heat dissipation from the lead frame 12E. Thus, the impedance mismatching between the portion where the window 11d is formed and the rest portion may be considerably compensated. FIG. 17 illustrates the optical module 10C according to the present embodiment with the flexible printed circuit board 22 connected to the lead frame 12E.

1. An optical module, comprising:
a lead frame;
a semiconductor optical device mounted on said lead frame;
a bonding wire connecting said lead frame with said semiconductor optical device; and
a resin that molds said lead frame, said semiconductor optical device and said bonding wire, said resin being transparent for light subject to said semiconductor optical device;
wherein said lead frame provides a screen bent at a position apart from said semiconductor optical device by a distance substantially equal to a dimension of said semiconductor optical device.

2. The optical module of claim 1,
wherein said screen is bent in a direction substantially in parallel to a direction that said bonding wire connected with said semiconductor optical device extends.

3. The optical module of claim 1,
wherein said screen is bent to cross an optical axis of said semiconductor optical device.

4. The optical module of claim 3,
wherein said screen provides an opening through which said optical axis of said semiconductor optical device passes.

5. The optical module of claim 1,
wherein said lead frame provides a thinned portion in a back surface opposite to a front surface where said semiconductor optical device is mounted, said lead frame being bent along said thinned portion.

6. The optical module of claim 1,
wherein said semiconductor optical device has a substantially rectangular plane shape, and said screen provides a sub-screen, said screen and said sub-screen surrounding said semiconductor optical device.

7. The optical module of claim 1,
wherein said resin provides a planar portion and a pillar portion, said semiconductor optical device being molded in said pillar portion, said lead frame being extracted from said planar portion.

8. The optical module of claim 7,
wherein said planar portion provides a window to expose said lead frame therein.

9. The optical module of claim 7,
wherein said lead frame provides a window in a portion molded in said planar portion, said window narrowing a cross section of said lead frame.

10. The optical module of claim 7,
further comprising a tubular member made of metal, said tubular member being adhered to said transparent resin.

11. The optical module of claim 7,
wherein said pillar portion buries a tubular member made of metal, said tubular member covering said semiconductor optical device.

12. The optical module of claim 1,
wherein said optical device is a semiconductor light emitting device,
wherein said optical module further includes a semiconductor light-receiving device that detects a magnitude of light emitted from said semiconductor optical device, said semiconductor photodiode being mounted on said lead frame, and
wherein said lead frame provides a tab bent from a surface of said lead frame that mounts said semiconductor optical device, said tab reflecting light emitted from said semiconductor light emitting device toward said semiconductor light-receiving device.

13. An optical module, comprising:
a lead frame;
a semiconductor optical device mounted on a primary surface of said lead frame;
a bonding wire electrically connecting said lead frame with said semiconductor optical device;
a resin molding said lead frame, said semiconductor optical device, and said bonding wire, said resin being transparent to light subject to said semiconductor optical device, said resin including a pillar portion and a planar portion, said pillar portion having a columnar outer shape and molding said semiconductor optical device and said primary surface of said lead frame, said planar portion being continuous to said pillar portion and extracting said lead frame; and
a tubular member made of metal surrounding said pillar portion, said tubular member being adhered to said pillar portion.

14. The optical module of claim 13,
wherein said tubular member envelopes said pillar portion.

15. The optical module of claim 13,
wherein said resin buries said tubular member therein.

16. The optical module of claim 15,
wherein said lead frame provides a pair of slits, said tubular member being inserted within said slits and supported by said lead frame.

17. The optical module of claim 13,
wherein said planar portion provides a window to expose said lead frame.

18. The optical module of claim 13,
wherein said lead frame provides a window in a portion molded in said planar portion to narrow a cross section of said lead frame.

19. A method to manufacture an optical module that molds a semiconductor optical device and a lead frame mounting said semiconductor optical device thereon with a resin transparent to light subject to said semiconductor optical device, said resin providing a pillar portion that installing said semiconductor optical device and a planar portion for extracting said lead frame, said planar portion providing a window to expose said lead frame, said method comprising steps of:
(a) mounting said semiconductor optical device on said lead frame and electrically connecting said lead frame with said semiconductor optical device with a bonding wire;
(b) molding said semiconductor optical device, said bonding wire and said lead frame with said resin to form said pillar portion and said planar portion;
(c) making a member in contact with said lead frame at said window in said planar portion; and
(d) soldering said lead frame extracted from said planar portion.

20. The method of claim 19,
further comprising a step of, after said soldering, filling a material in said window, said material having a dielectric constant substantially equal to a dielectric constant of said resin.

21. The method of claim 19,
further comprising a step of, after said step of electrically connecting said semiconductor optical device with said lead frame and before said step of molding, bending a portion of said lead frame to form a screen in a position apart from said semiconductor optical device by a distance comparable with a dimension of said semiconductor optical device.

22. The method of claim 21,
further comprising a step of, after said electrically connecting before said molding, covering said semiconductor optical device and a portion of said lead frame mounting said semiconductor optical device with a tubular member.
